(19) United States
(12) Patent Application Publication
(10) Pub. No.: US 2018/0048247 A1
(43) Pub. Date: Feb. 15, 2018

(54) Electricity Generating Wheel and Mat

(71) Applicant: Paul Gerstenberger, Morrison, CO (US)

(72) Inventor: Paul Gerstenberger, Morrison, CO (US)

(21) Appl. No.: 15/672,682

(22) Filed: Aug. 9, 2017

Related U.S. Application Data
(60) Provisional application No. 62/372,775, filed on Aug. 9, 2016.

(51) Int. Cl. H02N 1/08; H01L 41/113; H02N 2/18; H02J 5/00; H02M 3/07

(52) U.S. Cl. CPC H02N 1/08; H02J 5/005; H02M 3/073; H02N 2/181; H02N 2/183; H01L 41/113

(57) ABSTRACT

A DC generation and storage device including a power generation section with single or multiple layers of an electret film. A rectifier is connected to the electret film, which in turn is connected to a DC to DC or a DC to AC converter. A power storage device will be connected to the converter. This device is placed within a tire/wheel or a mat substructure described in many forms such that the act of putting pressure on the wheel/tire or the layered mat area as described by rolling or driving and by walking or running or other means will create electricity from day to day activity. The power in the tire is then transferred to a power storage device by means of a wireless charging system

### CROSS REFERENCES

The present application for patent claims priority to U.S. Provisional Patent Application No. 62/372,775 by Gerstenberger, entitled “Electricity Generating Wheel and Matt,” filed Aug. 9, 2016,” which is expressly incorporated herein.

### STATEMENT REGARDING FEDERALLY SPONSORED RESEARCH OR DEVELOPMENT

The electret material portion of the invention described herein was made with support of the U.S. Government, and the U.S. Government may have certain rights in the invention as provided for by the terms of Grant No. W31PQ-07-1-003 awarded by the Defense Advanced Research Projects Agency (DARPA).

### BACKGROUND

The following relates to materials which generate electricity when deformed and a converter circuit for the same.

Flexible material may be used to generate electricity from routine motions of individuals (e.g., walking). For example U.S. Pat. No. 6,433,465 uses the electrical response phenomenon of electrostrictive polymers in reverse to harvest or generate electrical power from human walking motion.

However alternative apparatuses and methods for recovering quantities of electricity from motion may provide increased efficiency and electricity production.

### SUMMARY

The described features generally relate to methods, systems, devices, or apparatuses for generating electricity from a wheel or a mat. Some embodiments relate to devices laid within a type of mat or flooring, roads, sidewalks and paths and within the tires of automobiles and other wheeled vehicles which generate electricity from the movement and pressing of those tires and of people, machinery and other things pressing on the ground, flooring, grass and roadwork of any kind.

An embodiment may comprise a DC to DC converter circuit. The circuit may include a voltage input terminal and a voltage output terminal together with a first capacitor element and a second capacitor element, where the second capacitor element comprises a plurality of individual capacitors. The circuit may further include a switch network which has a first phase wherein the plurality of capacitors are in series and connected to the first capacitor element and disconnected from the output terminal and a second phase wherein the plurality of capacitors are in parallel and connected to the output terminal and disconnected from the first capacitor element. Finally, there may be a switch controller that controls the switching between the phases. The switch controller monitors the voltage on the first terminal. The switching may be initiated only if the voltage in the first terminal is sufficiently high.

Another embodiment may comprise a DC generation device and storage device. The device may include a power generation section comprising multiple layers of an electret film. A rectifier may be connected to the electret film, which in turn may be connected to a DC to DC converter, for example the converter described immediately above. Finally, a power storage device (e.g., battery or capacitor) may be connected to the converter.

Another embodiment may include transferring gathered electricity to the battery system by means of a wireless charging system encompassed both inside and outside a tire.

Another embodiment may be the use of various configurations of the electret material inside of a tire or wheel along with other additions to the superstructure of the wheel or tire so that electricity can be collected and transferred.

Another embodiment may be the use of various configurations of the electret material inside, on top or underneath a mat of multiple sorts that can then generate and collect electricity from movement above or below the mat.

### BRIEF DESCRIPTION OF THE DRAWINGS

FIG. 1 illustrates an example of a power generating mat in accordance with aspects of the present disclosure.

FIG. 2 illustrates an example of a power generating tire in accordance with aspects of the present disclosure.

FIGS. 3A and 3B illustrate an example of an electret film in accordance with aspects of the present disclosure.

FIG. 4 illustrates an example of power generation from a tire or mat in accordance with aspects of the present disclosure.

FIG. 5 illustrates an example of a schematic representation of a electret film in accordance with aspects of the present disclosure.

FIG. 6 illustrates an example of a circuit in accordance with aspects of the present disclosure.

FIG. 7 illustrates an example of a circuit in accordance with aspects of the present disclosure.

FIG. 8 illustrates an example of the movement of electricity from a tire to a battery system by means of a wireless charging system in accordance with aspects of the present disclosure.

### DETAILED DESCRIPTION

As used in this specification, the following terms will be defined as follows.

“Tire” meaning any form of wheeled conveyance including but not limited to all State authorized vehicles permitted to drive on roads, bicycles, forklifts, tractors, wheeled machinery, etc.

“Mat” meaning any form of floor, road or trail covering which could be designed to hold the electret film or other generation device(s) for the purpose of generating electricity or energy by means of pressure either above or below.

“Mat” meaning any form of flat surface or any form of floor or road covering which could be designed capable of sandwiching something small between layers including but not limited to a rubber mat, any plastic, asphalt/cement or any amorphous material that can be laid on a road or on a walkway where traffic from walking persons to wheeled conveyances may cross.

“Electret film” means a polymer film which has been permanently charged, for example by radiation or corona discharge. In certain embodiments, the film has cavities, cells or voids and the cell walls have been charged after formation of the cavities. In one embodiment, the polymer film is polypropylene, but a great number of different polymers may be used, including but not limited to polyethylene, polytetrafluoroethylene, PVDF, polymethylpentene and cyclic olefin copolymer. In another example, the film is a foam layer having positive and negative charges on opposite internal void surfaces and at least one conductive coating on an outer surface of the layer. Some films may have conductive layers on both outer surfaces while other films may have no conductive layer. In certain embodiments, the cavity, cell, or void sizes will range between 1 μm and 1 mm or any range therein. Non-limiting examples of film thickness may be about 25 μm to about 1 mm or any range in between. Non-limiting examples of such electret films are found in U.S. Pat. Nos. 4,654,546, 6,852,402 and 7,376,239.

“Power storage device” means any existing or future developed device capable of storing electrical or other forms of energy including but not limited to batteries, capacitors or supercapacitors.

“Wireless Charging System” means current or future forms of wireless energy power transfer device capable of moving energy without the use of wires or other direct connections from the charging device or storage therein to other power storage devices.

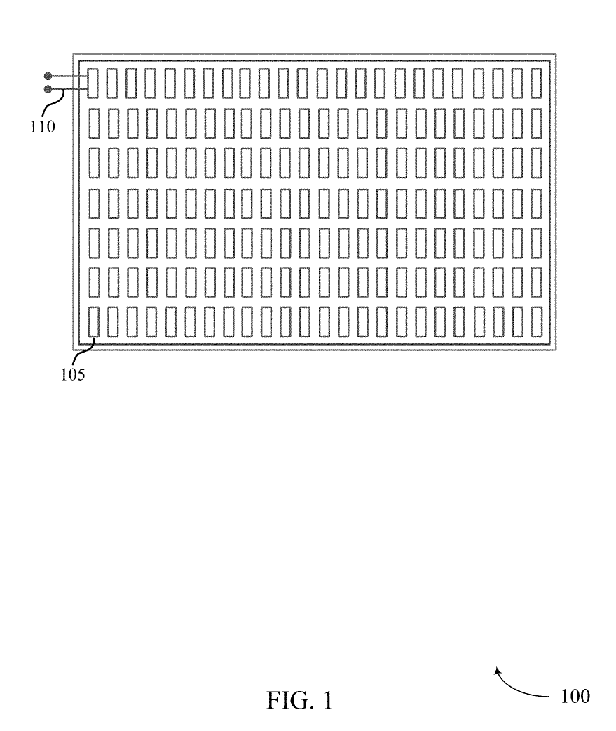

FIG. 1 illustrates an example of a power generating mat 100 in accordance with aspects of the present disclosure. Mat 100 may include one or more layers of electret film 105 as described herein running both vertically and horizontally inside or outside the two or more layers of the mat as described to generate electricity. The mat 100 may also include electrical leads 110 for electrically coupling the electret film 105 to other components such as a circuit, an energy storage device, or the like. In some examples, the multiple layers of the of electret film 105 may comprise a piezoelectric material.

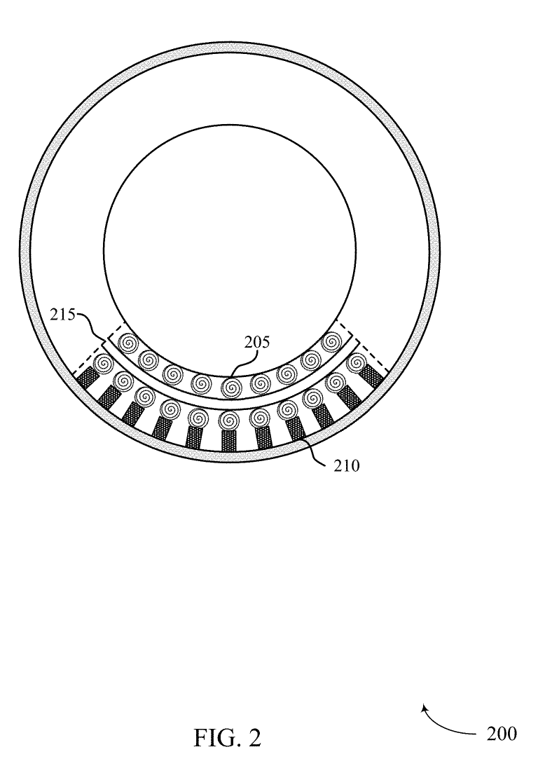

FIG. 2 illustrates an example of a power generating wheel or tire 200 in accordance with aspects of the present disclosure. Tire 200 may include a group or groupings of electret material 205 as described herein running the length and breadth of the tires contact with the ground or whatever it is riding upon inside of a layer of tire sandwiched with another layer of rubber or like flexible or non-flexible material inside. The electret material 205 may be an example of the electret film 105 described with reference to FIG. 1. Although FIG. 2 illustrates only a single layer around the center of the tire 200, other embodiments may have more layers side by side and also stacked on top of each other to create more electricity. Likewise there are other ways to place the electret material.

FIG. 2 also illustrates an example of a design including rows of rubber plates 210 raised from the inside floor of the tire 200 an amount of ½ inch or more (or less) with the layer or layers of electret film 205 riding above those plates inside of a “hammock” like structure 215 whereby the optimal amount of pressure may be put into the electret film rolls 205 by pressing against the hammocks containing them using the force of the roadway or other flooring to distend the tire inward creating that force. In some examples, the plates 210 may be rubber press plates and the electret film coils 515 may be rolled or layered. In some examples, the “hammock” like structure 215 may be rubber or another flexible material and the electric film may be rolled or layered.

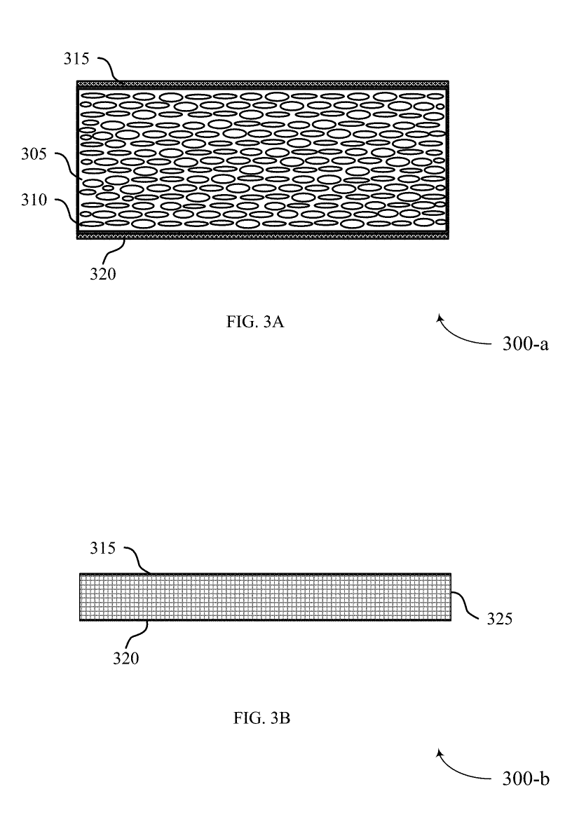

FIG. 3A illustrates an example of an electret film 300-a as disclosed in U.S. Pat. No. 4,654,546. The electret film 300-a may include a plastic matrix 305 having voids or blisters 310 and positively or negatively polarized metal films 315 and 320 on an upper and lower surface of the plastic matrix.

FIG. 3B illustrates a schematic representation of an electret film 300-b including ferroelectric film 325.

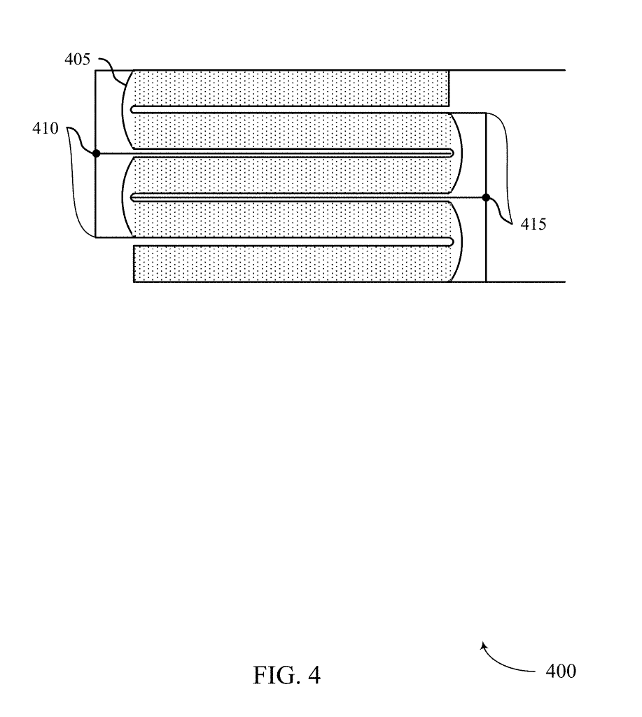

FIG. 4 illustrates an example of how the power generation section 400 for a tire (e.g., tire 200 from FIG. 2) may be formed. As shown in FIG. 4, an electret film 405 may be folded and stacked. The electret film 405 may be an example of aspects of electret film 105 described with reference to FIG. 1 (e.g., similar to FIG. 2A in U.S. Pat. No. 4,654,546). The folds at bends 405 may result in the same polarity metal surfaces being in contact with one another. Electrical leads 410 and 415 may extend within the folds of the film 405 such that electrical leads 415 contact only one side (i.e., one metal surface layer) of the film 405 and electrical leads 410 only contact the opposite side (polarity) of the film 405.

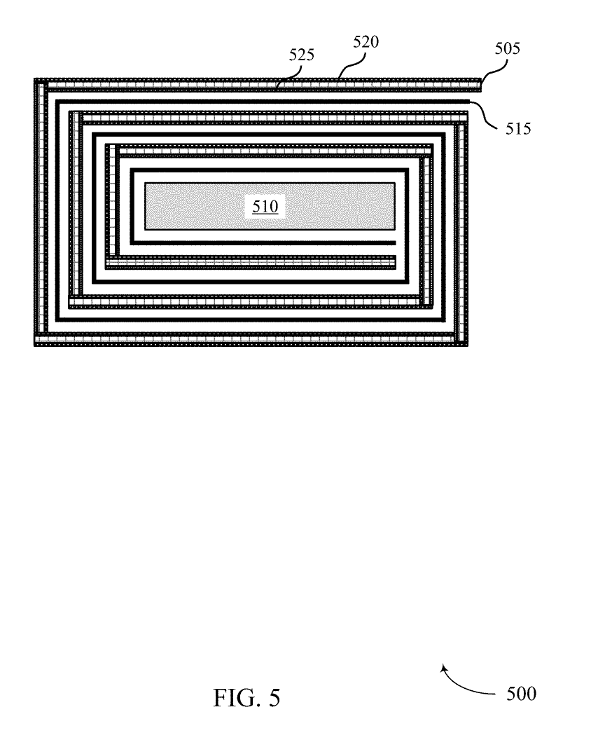

FIG. 5 illustrates an example of how the power generation section 500 for a shoe may be formed. As shown in FIG. 5, an electret film 505 may be rolled. The electret film 505 may be an example of aspects of electret film 105 described with reference to FIG. 1. In the embodiment shown, the electret film 505 may be wound around a mechanical support 510. The purpose of the mechanical support 510 is to enable rolling of the film 505 and to keep the film 505 stack in shape after rolling. The support 510 may be made from low weight material such as plastic or wood or another dielectric material. In addition, electrical contacts (e.g., such as electrical contacts 110 described with reference to FIG. 1) to the film 505 can be made by way of the support. In one embodiment, the support 510 is a circuit board with electrodes patterned for electrical contact to the film 505. In other embodiments, the mechanical support 510 may be optional.

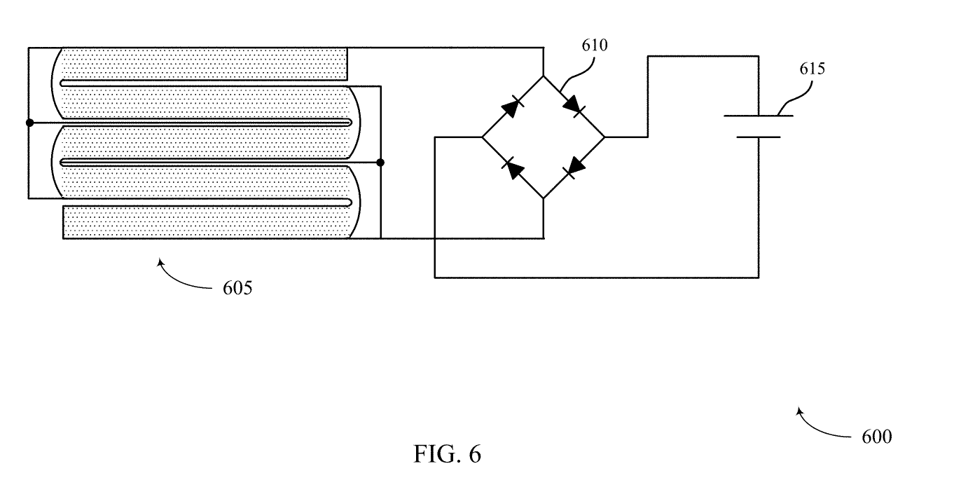

An insulating film 515 may be positioned between the wound layers of the electret film 505 in order that the opposing (polarity) metal surfaces 520 and 525 do not come into electrical contact. In one example, the film thickness is about 50 μm and the total film stack thickness is about 1 cm. Thus, in this example, the total stack would consist of about 100 wraps. The energy output from the film 505 is proportional to the total charge generated. This is proportional to the film area. A larger number of wraps and hence a larger total film area is more readily obtained with a thin film. Some embodiments maintain the film thickness above 10-20 μm as thinner films may be more difficult to handle and process. Although not explicitly show, it will be understood that electrical leads may be attached to metal surfaces 520 and 525 and could connect with a circuit such as illustrated in FIG. 6.

FIG. 6 illustrates an example of a circuit 600 which may be used in conjunction with a power generating section 605. The power generating section 605 may be an example of aspects of the tire 200 described with reference to FIG. 2, the power generation section 400 described with reference to FIG. 4, or the power generation section 500 described with reference to FIG. 5. In this circuit 600, a conventional rectifier 610 may connect to (e.g., electrically couple with) the electrical leads of the folded or rolled electret film from the power generating section 605 (e.g., as shown in FIG. 4) and ensures only a DC current of the correct polarity is directed to a storage device 615 (e.g., a battery) or used immediately. When force is applied to the film of the power generating section 605, it will generate charge Q. This charge is delivered to the storage device 615 with a voltage V and the total energy is delivered to the storage device 615 is E=QV. In some examples, the storage device 615 may be a battery or a capacitor.

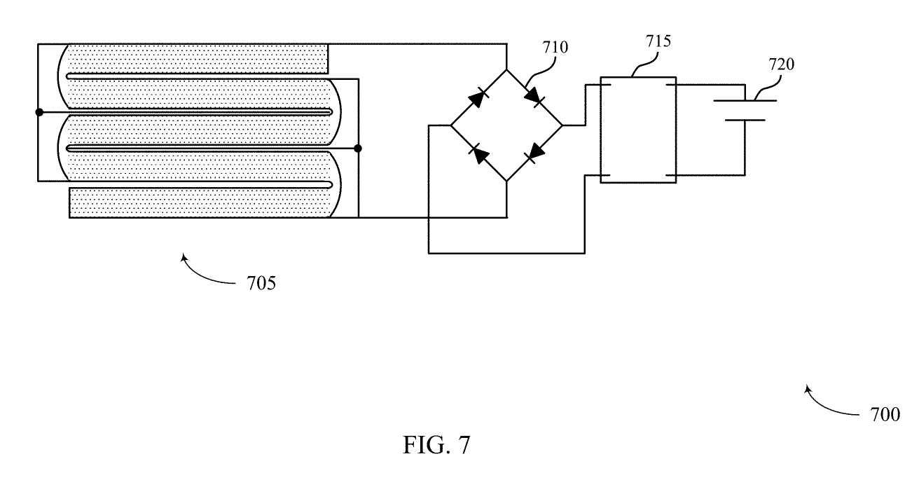

FIG. 7 illustrates an example of a circuit 700 that is similar to the circuit 600 described with reference to FIG. 6, but further illustrates a conventional stepdown DC to DC converter 715 positioned between rectifier 710 and battery 720. The step down converter 715 allows higher voltages at the rectifier output than is practical when connecting the rolled/folded electret film stack (e.g., from the power generating section 705) directly to a storage device. Because piezoelectric transducers typically have high electrical impedances the output power will be small unless comparatively higher voltages are used. For example, if the DC voltage is 90 V, the energy generated by the transducer is E=QV, is 30 higher than in FIG. 6 where the power generating section is connected to a 3 volt battery without being stepped down.

In some examples the converter 715 may include a voltage input terminal and a voltage output terminal and a first and second capacitor element. The second capacitor element may include a plurality of individual capacitors. The converter 715 may also include a switch network comprising a first phase wherein the plurality of capacitors are in series to the first capacitor element and disconnected from the output terminal. The switch network may also include a second phase wherein the plurality of capacitors are in parallel with the output terminal and disconnected from the first capacitor element. The converter 715 may also include a switch controller that switches to the second phase when a first voltage is created across the first capacitor element and that switches to the first phase when a second, lower voltage is created across the first capacitor element. The switch controller may include an oscillator that turns on when the first voltage is reached.

In some examples diodes may be positioned between the individual capacitors in the second capacitor element such that the individual capacitors may be switches between the parallel phase and the series phase.

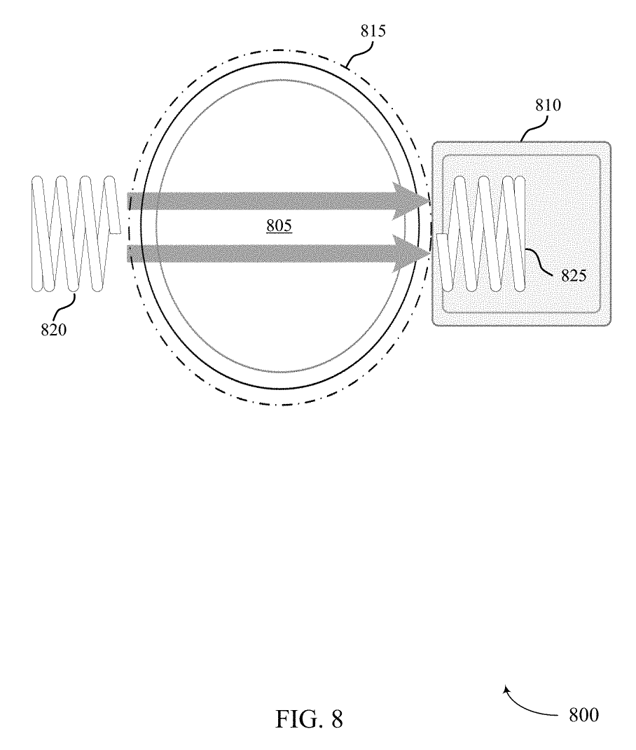

FIG. 8 illustrates an example of the movement of electricity 805 from the tire (or some other energy generating section) to the battery system 810 by means of a wireless charging system 815. The device may further include a primary charging unit carried within the tire including a charging circuit and a primary coil 820 for inductively providing power to an external capture device including secondary coil 825.

Although the above disclosure has been described in terms of certain specific embodiments, it will be understood that many other obvious modifications and variations may be made to the present invention. All such modifications and variations are intended to fall within the scope of the following claims.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A power generating tire comprising:
a. a power generation section comprising multiple layers of an electromechanical transducer material positioned inside or anywhere on the tire;
b. a rectifier connected to the electromechanical transducer material;
c. a DC to DC converter connected to the rectifier, the converter
comprising:
i. a voltage input terminal and a voltage output terminal;
ii. at least a first capacitor element and a second capacitor element, wherein the second capacitor element comprises a plurality of individual capacitors;
iii. a switch network comprising;
1. a first phase wherein the plurality of capacitors are in series to the first capacitor element and disconnected from the output terminal; and
2. a second phase wherein the plurality of capacitors are in parallel with the output terminal and disconnected from the first capacitor element; and
iv. a switch controller which switches to the second phase when a first voltage is created across the first capacitor element and which switches to the first phase when a second, lower voltage is created across the first capacitor element; and
d. a power storage device electrically coupled with the converter.

2. The power generating tire of claim 1, wherein the multiple layers are formed by a folded electret film.

3. The power generating tire of claim 1, wherein the multiple layers are formed by rolling an electret film.

4. The power generating tire of claim 3, wherein an insulating material is placed between layers of the rolled electret film.

5. The power generating tire of claim 1, wherein diodes are positioned between the individual capacitors in the second capacitor element such that the individual capacitors may be switched between the parallel phase and the series phase.

6. The power generating tire of claim 1, wherein the switch controller comprises an oscillator which turns on when the first voltage is reached.

7. The power generating tire of claim 1, wherein the multiple layers comprises a piezoelectric material.

8. A power generating tire comprising:
a tire body having a cavity running the circumference of the tire in multiple layers either parallel to a contact material or horizontal from it; and
a power generation section positioned in the cavity and comprising single or multiple layers of folded or rolled electret film or other electricity generating pliable or non-pliable material.

9. The power generating tire of claim 8, wherein the electret film comprises a deformable, permanently charged, polymer layer with cells formed therein and two conductive layers on a first and second sides of the polymer layer.

10. The power generating tire of claim 8, further comprising:
a rectifier and a power storage device electrically coupled with the electret film.

11. The power generating tire of claim 8, further comprising:
a wireless charging system carried within the tire and configured to wirelessly transfer power to a power storage device.

12. A power generating mat comprising:
a. a power generation section comprising multiple layers of an electromechanical transducer material positioned in or on a multiple layered surface;
b. a rectifier connected to the electromechanical transducer material;
c. a DC to DC converter connected to the rectifier, the converter comprising:
i. A voltage input terminal and a voltage output terminal;
ii. At least a first capacitor element and a second capacitor element, wherein the second capacitor element comprises a plurality of individual capacitors;
iii. A switch network comprising;
1. a first phase wherein the plurality of capacitors are in series to the first capacitor element and disconnected from the output terminal; and
2. a second phase wherein the plurality of capacitors are in parallel with the output terminal and disconnected from the first capacitor element; and
iv. a switch controller which switches to the second phase when a first voltage is created across the first capacitor element and which switches to the first phase when a second, lower voltage is created across the first capacitor element; and
d. a power storage device is electrically coupled with the converter.

13. The power generating mat of claim 12, wherein the multiple layers are placed with single or multiple layers formed by a folded electret film.

14. The power generating mat of claim 13, wherein an insulating material is placed between layers of the rolled electret film.

15. The power generating mat of claim 12, wherein diodes are positioned between the individual capacitors in the second capacitor element such that the individual capacitors may be switched between the parallel phase and the series phase.

16. The power generating mat of claim 12, wherein the switch controller comprises an oscillator which turns on when the first voltage is reached.

17. The power generating mat of claim 12, wherein the multiple layers comprises a piezoelectric material.

18. The power generating mat of claim 12, further comprising:
a cavity or multiple cavities running the length or breadth of the mat in single or multiple layers either parallel to a contact material or horizontal from it; and
a power generation section positioned in the cavity and comprising single or multiple layers of folded or rolled electret film or other electricity generating pliable or non-pliable material.

19. The power generating mat of claim 12, wherein the electret film comprises a deformable, permanently charged, polymer layer with cells formed therein and two conductive layers on the first and second sides of the polymer layer.

20. The power generating mat of claim 12, further comprising:
a rectifier and a power storage device electrically coupled with the electret film.
